(19) United States
(12) Patent Application Publication
(10) Pub. No.: US 2024/0334781 A1
(43) Pub. Date: Oct. 3, 2024

(54) Display Panel and Preparation Method Therefor

(71) Applicant: HKC CORPORATION LIMITED, Shenzhen (CN)

(72) Inventors: Tianjun HUANG, Shenzhen (CN); Jing LI, Shenzhen (CN); Haijiang YUAN, Shenzhen (CN)

(73) Assignee: HKC CORPORATION LIMITED, Shenzhen (CN)

(21) Appl. No.: 18/620,691

(22) Filed: Mar. 28, 2024

(30) Foreign Application Priority Data
Mar. 28, 2023 (CN) 202310311418.3

(51) Int. Cl. H10K 59/80; G06F 3/041; G06F 3/044; H10K 59/12; H10K 59/122; H10K 59/40

(52) U.S. Cl. CPC H10K 59/80522; G06F 3/0412; H10K 59/1201; H10K 59/122; H10K 59/40; G06F 3/0446; G06F 2203/04103

(57) ABSTRACT

The present application relates to a display panel and a preparation method therefor. The display panel includes a plurality of auxiliary electrodes located on one side of a pixel limiting layer facing away from an array substrate, at least part of the auxiliary electrodes is located in pixel openings, second electrode layers are disconnected at edges of the auxiliary electrodes, the auxiliary electrodes include conductive portions and covering portions located on one sides of the conductive portions facing away from the array substrate, and orthographic projections of the covering portions on the array substrate cover orthographic projections of the conductive portions on the array substrate; and peripheral edges of the sub-pixels of the pixel units are not parallel to a direction where a long edge or a short edge of the display panel is located, the auxiliary electrodes are arranged close to the peripheral edge of the at least one sub-pixel, and the auxiliary electrodes extend parallel to the direction where the long edge and the short edge are located, so that ends of the second electrode layers are capable of overlapping with the conductive portions to achieve electrical connection.

### CROSS REFERENCE TO RELATED APPLICATIONS

The present application claims the priority of the Chinese patent application No. 202310311418.3 entitled “Display Panel and Preparation Method Therefor” and filed on Mar. 28, 2023, the entire contents of which is incorporated herein by reference.

### TECHNICAL FIELD

The present application relates to the technical field of display, in particular to a display panel and a preparation method therefor.

### BACKGROUND

As a size of an organic light emitting diode (OLED) display panel increases, a cathode layer area of a light-emitting element will also increase. A cathode layer of a top-emitting OLED display panel needs to meet the requirements of light transmittance and cannot be too thick. This large area of cathode layer will inevitably lead to in-plane voltage drop (IR-Drop), affecting brightness uniformity of a display image. For this reason, in the related art, an auxiliary electrode is usually arranged on a pixel limiting layer to overlap with the cathode layer, and the auxiliary electrode is used to reduce overall resistance of the cathode layer. In addition, a light-emitting device usually uses a fine metal mask as shielding, and deposition of tricolor sub-pixels is performed through an evaporation process. However, for a large-sized OLED display panel, an original evaporation process is no longer applicable due to the excessive sag of the metal mask.

The related art has begun to use a mode of combination of evaporation and etching. That is, the evaporation process is used first to form a film on the entire surface. With a special structure of an evaporation source, cathode ends of the sub-pixels can form an overlap with the auxiliary electrode. Then, a substrate after film formation is etched through a photolithographic process to separate the tricolor sub-pixels. However, the sub-pixels are generally of rectangular structures, that is, edge directions of the sub-pixels must be perpendicular to an evaporation so as to ensure good overlap between the auxiliary electrode and the cathode layer. When using sub-pixels with diamond or other irregular structures with better display effects, the cathode layer and the auxiliary electrode are poor in overlap effect, and even unable to overlap, resulting in abnormal display.

### SUMMARY

The objective of the present application is to provide a display panel and a preparation method therefor. The display panel can form effective overlap between a cathode layer with irregular sub-pixels and an auxiliary electrode, so as to relieve a problem of abnormal display.

In a first aspect, an embodiment of the present application provides a display panel, having a long edge and a short edge which are perpendicular to each other. The display panel includes an array substrate, as well as a pixel limiting layer and a light-emitting functional layer formed sequentially on the array substrate, a plurality of first electrodes arranged in an array are formed on the array substrate, the pixel limiting layer includes a plurality of pixel openings, and the pixel openings expose at least part of the first electrodes; the light-emitting functional layer includes a plurality of pixel units, the pixel units include a plurality of sub-pixels, and the sub-pixels include light-emitting structures located on the first electrodes and second electrode layers located on the light-emitting structures; the display panel further includes a plurality of auxiliary electrodes located on one side of the pixel limiting layer facing away from the array substrate, at least part of the auxiliary electrodes is located in the pixel openings, the second electrode layers are disconnected at edges of the auxiliary electrodes, the auxiliary electrodes include conductive portions and covering portions located on one sides of the conductive portions facing away from the array substrate, and orthographic projections of the covering portions on the array substrate cover orthographic projections of the conductive portions on the array substrate, wherein peripheral edges of the sub-pixels of the pixel units are not parallel to a direction where the long edge or the short edge of the display panel is located, the auxiliary electrodes are arranged close to the peripheral edge of the at least one sub-pixel, and the auxiliary electrodes extend parallel to the direction where the long edge and the short edge are located, so that ends of the second electrode layers are capable of overlapping with the conductive portions to achieve electrical connection.

In a second aspect, an embodiment of the present application further provides a preparation method of a display panel, including: providing an array substrate, wherein a plurality of first electrodes arranged in an array are formed on the array substrate; forming a pixel limiting layer on the array substrate, wherein the pixel limiting layer includes a plurality of pixel openings, and the pixel openings expose at least part of the first electrodes; forming a plurality of auxiliary electrodes on the pixel limiting layer, wherein at least part of the auxiliary electrodes is located in the pixel openings, the auxiliary electrodes include conductive portions and covering portions located on one sides of the conductive portions facing away from the array substrate, and orthographic projections of the covering portions on the array substrate cover orthographic projections of the conductive portions on the array substrate; and evaporating a light-emitting functional layer on the pixel limiting layer and the plurality of auxiliary electrodes, wherein the light-emitting functional layer includes a plurality of pixel units, the pixel units include a plurality of sub-pixels, the sub-pixels include light-emitting structures located on the first electrodes and second electrode layers located on the light-emitting structures, and the second electrode layers are disconnected at edges of the auxiliary electrodes; and peripheral edges of the sub-pixels are not parallel to a direction where a long edge or a short edge of the display panel is located, the auxiliary electrodes are arranged close to the peripheral edge of the at least one sub-pixel, and the auxiliary electrodes extend parallel to a direction where the long edge and the short edge are located, so that the second electrode layers are capable of overlapping with the conductive portions to achieve electrical connection.

According to the display panel and the preparation method therefor provided by the embodiments of the present application, the display panel includes the array substrate, the pixel limiting layer and the light-emitting functional layer which are sequentially formed on the array substrate, and the plurality of auxiliary electrodes located on one side of the pixel limiting layer facing away from the array substrate, the plurality of first electrodes arranged in an array are formed on the array substrate, the pixel limiting layer includes the plurality of pixel openings, and the pixel openings expose at least part of the first electrodes; the light-emitting functional layer includes a plurality of pixel units, and the pixel units include the plurality of sub-pixels; the sub-pixels include light-emitting structures located on the first electrodes and second electrode layers located on the light-emitting structures; and the auxiliary electrodes include conductive portions and covering portions located on one sides of the conductive portions facing away from the array substrate, and orthographic projections of the covering portions on the array substrate cover orthographic projections of the conductive portions on the array substrate. By arranging the auxiliary electrodes close to the peripheral edge of the at least one sub-pixel, and making the auxiliary electrodes extend parallel to the direction where the long edge and the short edge of the display panel are located, the second electrode layers are capable of overlapping with the conductive portions to achieve the electrical connection. As a result, second electrode layers (i.e., cathode layers) with irregular sub-pixels can be made suitable for existing commonly used evaporation equipment for evaporating rectangular sub-pixels, allowing for forming of effective overlap between the second electrode layers and the auxiliary electrodes, thereby improving uniformity of display brightness without the need for additional development of the evaporation equipment, which has high feasibility and greatly reduces a manufacturing cost while meeting a better display effect.

### BRIEF DESCRIPTION OF DRAWINGS

Features, advantages, and technical effects of exemplary embodiments of the present application will be described with reference to accompanying drawings. In the accompanying drawings, the same part uses the same reference numeral. The accompanying drawings are not drawn to the actual scale and are only used to illustrate the relative positional relationship. A layer thickness in certain parts is drawn in an exaggerated mode for better understanding. The layer thickness in the accompanying drawings does not represent a proportional relationship of an actual layer thickness.

FIG. 1 shows a schematic top view of a display panel provided by a first embodiment of the present application.

FIG. 2 shows a schematic structural diagram of a sub-pixel of a pixel unit in

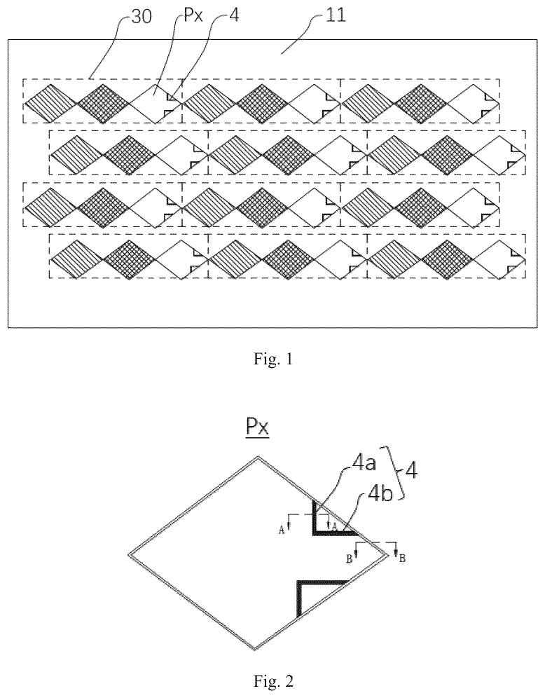

FIG. 1.

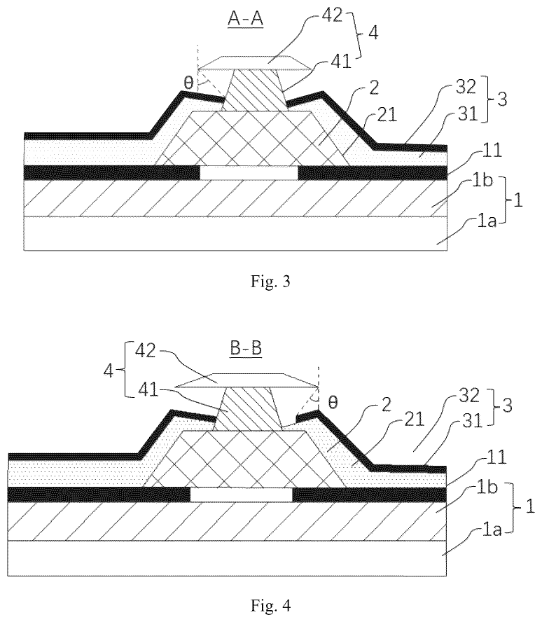

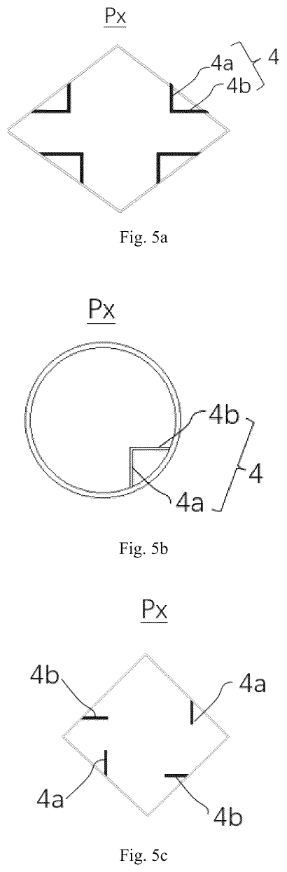

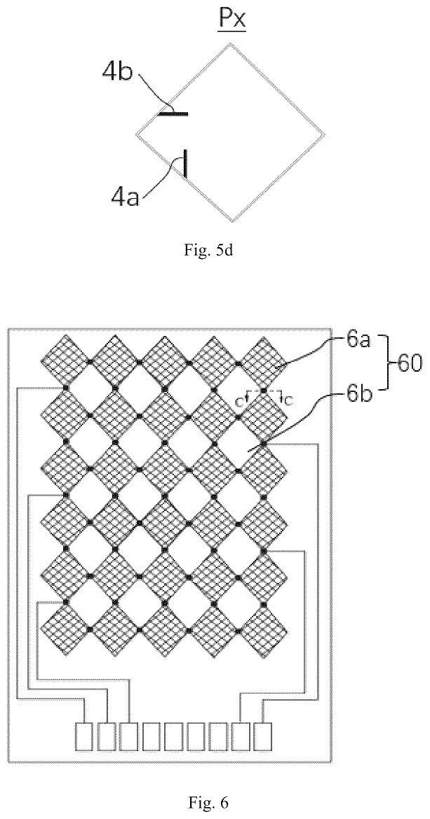

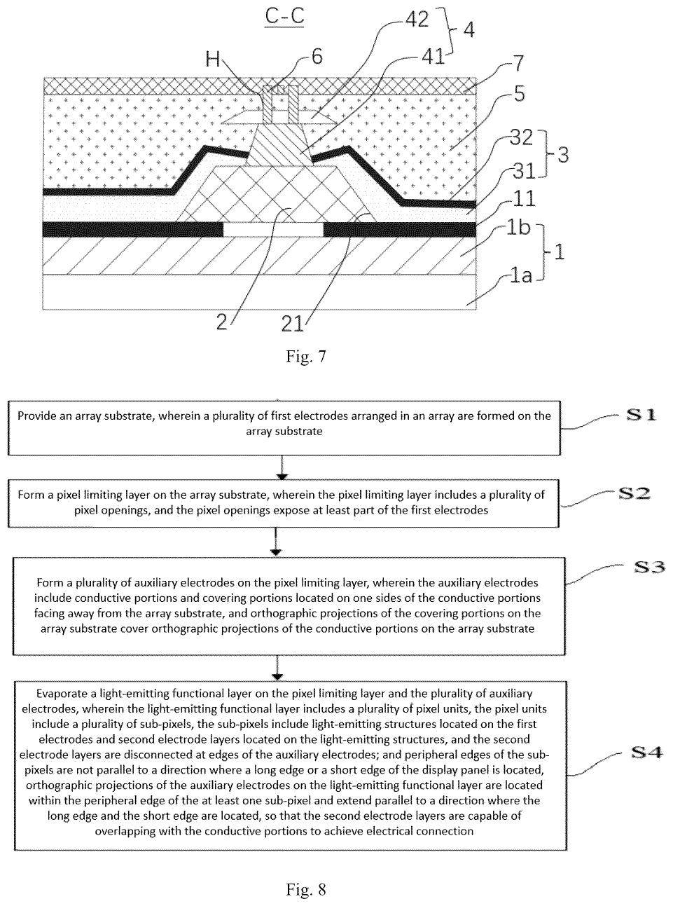

FIG. 3 shows a cross-sectional view in a direction A-A in FIG. 2.

FIG. 4 shows a cross-sectional view of an auxiliary electrode arranged in a direction B-B in the related art.

FIG. 5a to FIG. 5d show several deformation structures of a sub-pixel in FIG. 1.

FIG. 6 shows a schematic top view of a display panel provided by a second embodiment of the present application.

FIG. 7 shows a cross-sectional view in a direction C-C in FIG. 6.

FIG. 8 is a flow block diagram of a preparation method of a display panel provided by an embodiment of the present application.

### DESCRIPTION OF REFERENCE NUMERALS

1, Array substrate; 1a, Substrate; 1b, Driving array layer; 11, First electrode;
2, Pixel limiting layer; 21, Pixel opening;
3, Light-emitting functional layer; 30, Pixel unit; Px, Sub-pixel; 31, Light-emitting structure; 32, Second electrode layer;
4, Auxiliary electrode; 4a, First transfer portion; 4b, Second transfer portion; 41, Conductive portion; 42, Covering portion;
5, Planarization layer; 6, Touch control layer; H, Via hole; 60, Touch control electrode; 6a, Touch control driving electrode; 6b, Touch control sensing electrode; 7, Encapsulation layer; 0, Evaporation angle.

### DETAILED DESCRIPTION

Features and exemplary embodiments of various aspects of the present application will be described below in detail. In the detailed description below, many specific details are presented to provide a comprehensive understanding of the present application. However, it is apparent to those skilled in the art that the present application may be implemented without the need for some of these specific details. The following description of the embodiments is only intended to provide a better understanding of the present application by illustrating examples of the present application. In the accompanying drawings and the following description, at least some well-known structures and technologies are not shown to avoid unnecessary ambiguity to the present application; and, for clarity, a size of a regional structure may be exaggerated. In addition, the features, structures, or characteristics described below may be combined in one or more embodiments in any suitable manner.

### First Embodiment

As shown in FIG. 1 to FIG. 4, a display panel provided by a first embodiment of the present application has a long edge and a short edge which are perpendicular to each other. The display panel includes an array substrate 1, as well as a pixel limiting layer 2 and a light-emitting functional layer 3 formed sequentially on the array substrate 1, a plurality of first electrodes 11 arranged in an array are formed on the array substrate 1, the pixel limiting layer 2 includes a plurality of pixel openings 21, and the pixel openings 21 expose at least part of the first electrodes 11; and the light-emitting functional layer 3 includes a plurality of pixel units 30, the pixel units 30 include a plurality of sub-pixels Px (also known as light-emitting elements), and the sub-pixels Px include light-emitting structures 31 located on the first electrodes 11 and second electrode layers 32 located on the light-emitting structures 31.

The array substrate 1 includes a substrate 1a and a driving array layer 1b located on the substrate 1a, and the driving array layer 1b includes a pixel circuit. The plurality of first electrodes 11 are formed on the driving array layer 1b. A material of the substrate 1a may be glass or polyimide.

Optionally, the sub-pixels Px further include first common layers and second common layers. The first common layers include hole injection layers (HIL) located on the first electrodes 11 and hole transport layers (HTL) located on surfaces of one sides of the hole injection layers facing away from the array substrate 1. The second common layers include electron transport layers (ETL) located on surfaces of the light-emitting structures 31 and electron injection layers (EIL) located on surfaces of one sides of the electron transport layers facing away from the light-emitting structures 31.

The display panel further includes a plurality of auxiliary electrodes 4 located on one side of the pixel limiting layer 2 facing away from the array substrate 1, at least part of the auxiliary electrodes is located in the pixel openings 21, the second electrode layers 32 are disconnected at edges of the auxiliary electrodes 4, the auxiliary electrodes 4 include conductive portions 41 and covering portions 42 located on one sides of the conductive portions 41 facing away from the array substrate 1, and orthographic projections of the covering portions 42 on the array substrate 1 cover orthographic projections of the conductive portions 41 on the array substrate 1.

Peripheral edges of the sub-pixels Px of the pixel units 30 are not parallel to a direction where the long edge or the short edge of the display panel is located, the auxiliary electrodes 4 are arranged close to the peripheral edge of the at least one sub-pixel Px, and the auxiliary electrodes 4 extend parallel to the direction where the long edge and the short edge are located, so that ends of the second electrode layers 32 are capable of overlapping with the conductive portions 41 to achieve electrical connection.

In the present application, the display panel is of a top-emitting structure, the first electrodes 11 are anodes and the second electrode layers 32 are cathodes laid on a whole surface. The second electrode layers 32 are disconnected at the edges of the auxiliary electrodes 4 to allow the edges of the auxiliary electrodes 4 to be capable of overlapping and connecting with the conductive portions 41 of the auxiliary electrodes 4, thereby reducing an integral resistance of the second electrode layers 32 using the auxiliary electrodes 4.

Optionally, the at least one sub-pixel in the at least one pixel unit 30 is provided with the auxiliary electrode 4. The more auxiliary electrodes 4 there are, the smaller the integral resistance drop of the second electrode layers 32, which is beneficial for improving the brightness uniformity of the display panel.

Furthermore, the display panel is of a rectangular structure, with the long edge extending in a horizontal direction and the short edge extending in a vertical direction. In order to improve the display effect, the sub-pixels Px are each of an irregular structure, and its peripheral edges are not parallel to the direction where the long edge or the short edge of the display panel is located.

As shown in FIG. 2 and FIG. 4, the sub-pixels Px are each of a rhombic structure, and its four edges form a certain included angle with the direction where the long edge (the horizontal direction) of the display panel is located or the direction where the short edge (the vertical direction) of the display panel is located. If a conventional evaporation process is used to arrange the auxiliary electrodes 4 at B-B, due to a size of an evaporation angle θ of an evaporation source generally applies to the rectangular sub-pixels, when the sub-pixels Px are each of the rhombic structure, due to the larger outer contour size of the sub-pixels Px, especially the longer diagonal lines, under the same process conditions, limited by the size of the evaporation angle θ, a larger evaporation angle θ is required when evaporating the second electrode layers 32 so as to make the second electrode layers 32 be overlapped and connected with the conductive portions 41, with the need of additionally developing evaporation equipment, which greatly increases the manufacturing cost.

For this purpose, as shown in FIG. 2 and FIG. 3, the auxiliary electrodes 4 are arranged close to the peripheral edge A-A of the at least one sub-pixel Px, the auxiliary electrodes 4 extend parallel to the direction where the long edge and the short edge are located, similar to the long edge or the short edge of the rectangular sub-pixel, and the outer contour size is reduced, so that the irregular sub-pixels can still be suitable for an existing evaporation source and evaporation process, to ensure that the ends of the second electrode layers 32 can overlap with the conductive portions 41 to achieve electrical connection without the need for additional development of evaporation equipment, which has high feasibility and greatly reduces the manufacturing cost while meeting the better display effect.

In some embodiments, shapes of the sub-pixels Px are any one or a combination of at least two of a circle, an ellipse, or a polygon. The plygon may be polygons such as but not limited to a triangle, a trapezoid, a long strip shape, a pentagon, and a hexagon. In the pixel units, the shapes of all the sub-pixels Px may be the same or different, depending on the specific pixel layout structure. Because there is a certain included angle between the at least one edge of the sub-pixels Px and the direction where the long edge (the horizontal direction) of the display panel is located or the direction where the short edge (the vertical direction) of the display panel is located, if the auxiliary electrodes 4 are arranged in an extension direction of this edge, it will not be able to meet the requirement of the evaporation angle θ. The auxiliary electrodes 4 need to be arranged close to the edge and extend parallel to the direction where the long edge and the short edge are located, so that the second electrode layers 32 can be overlapped and connected with the conductive portion 41.

FIG. 5a to FIG. 5d show several deformation structures of the sub-pixel in FIG. 1.

In some embodiments, the auxiliary electrodes 4 include first transfer portions 4a and second transfer portions 4b which are arranged perpendicular to and intersecting with each other, and the auxiliary electrodes 4 are arranged close to at least one edge of the peripheral edges of the sub-pixels Px. At least part of the first transfer portions 4a and the second transfer portions 4b are located within the pixel openings 21. Because the first transfer portions 4a and the second transfer portions 4b, which are arranged perpendicular to and intersecting with each other, are similar to the two mutually-perpendicular edges of the rectangular sub-pixels, the irregular sub-pixels can be made still applicable to the existing evaporation source and evaporation process, ensuring that the ends of the second electrode layers 32 can overlap with the conductive portions 41 to achieve the electrical connection.

As shown in FIG. 5a, the sub-pixels Px are each of a parallelogram or a rhombic structure with an acute angle, and the auxiliary electrodes 4 are arranged close to four edges of the peripheral edges of the sub-pixels Px. Such setting can ensure that the second electrode layers 32 and the conductive portions 41 of the auxiliary electrodes 4 can be overlapped and connected, improving the reliability of the evaporation process. As shown in FIG. 2, the sub-pixels Px are each of a parallelogram or a rhombic structure with an acute angle, and the auxiliary electrodes 4 are arranged close to two edges of the peripheral edges of the sub-pixels Px. Each auxiliary electrode 4 includes first transfer portions 4a and second transfer portions 4b which are arranged perpendicular to and intersecting with each other. Compared with the sub-pixel Px structure shown in FIG. 5a, on the premise that the second electrode layers 32 and the conductive portions 41 of the auxiliary electrodes 4 can be overlapped and connected, an occupied space of the auxiliary electrodes 4 can be reduced, and a pixel aperture ratio can be increased.

As shown in FIG. 5b, the sub-pixels Px are each of a circular structure, and some regions of the circular sub-pixels remain perpendicular to an evaporation direction, thereby meeting the requirement of the evaporation angle θ. Therefore, one auxiliary electrode 4 is preferred. The auxiliary electrode 4 may be arranged at any position of the circular sub-pixels Px close to the edge, as long as it has the first transfer portions 4a and second transfer portions 4b which are arranged perpendicular to and intersecting with each other.

In some embodiments, the auxiliary electrodes 4 include first transfer portions 4a and second transfer portions 4b which are arranged perpendicular to each other and at intervals, the peripheral edges of the sub-pixels Px include a plurality of edges, and the first transfer portions 4a and the second transfer portions 4b are arranged respectively close to different edges.

As shown in FIG. 5c, the sub-pixels Px are each of a rhombic structure with a right angle. The first transfer portions 4a and the second transfer portions 4b of the auxiliary electrodes 4 are arranged perpendicular to each other and at intervals, and are arranged respectively close to different edges. The first transfer portions 4a are arranged on the two edges, and the second transfer portions 4b are arranged on the other two edges.

Because the sub-pixels Px are each of the rhombic structure with the right angle, adding the auxiliary electrodes 4 will occupy a part of space of the sub-pixels Px, and result in a loss of the aperture ratio. Arranging the first transfer portions 4a and the second transfer portions 4b perpendicular to each other and at the different edges of the sub-pixels Px at intervals can reduce the occupation space of the auxiliary electrodes 4 and increase the pixel aperture ratio.

Further, as shown in FIG. 5d, the sub-pixels Px are each of a rhombic structure with a right angle. The first transfer portions 4a and second transfer portions 4b of the auxiliary electrodes 4 are arranged perpendicular to each other and at intervals, and are arranged respectively close to two different edges. The first transfer portions 4a are arranged on the one edge, and the second transfer portions 4b are arranged on the other edge. Compared with the sub-pixel Px structure shown in FIG. 5c, the occupation space of the auxiliary electrodes 4 can further be reduced, thereby increasing the pixel aperture ratio.

It may be understood that the specific structure and position of the auxiliary electrodes 4 at the peripheral edges of the sub-pixels Px are not limited to the diagram, and more forms can be set according to the specific voltage drop distribution of the display panel, which is not repeated.

Further, a ratio between lengths of the auxiliary electrodes 4 parallel to the direction where the long edge or the short edge is located and lengths of maximum outer contour diameters of the sub-pixels Px is greater than 1:10.

If the lengths of the auxiliary electrodes 4 are too long, it will also occupy more space of the sub-pixels Px, affecting the pixel aperture ratio. The inventor found through practical research that the ratio between lengths of the auxiliary electrodes 4 parallel to the direction where the long edge or the short edge is located and lengths of maximum outer contour diameters of the sub-pixels Px is greater than 1:10, which can achieve a balance between the overlap and connection of the second electrode layers 32 and the conductive portions 41 of the auxiliary electrodes 4 and the pixel aperture ratio. For example, the sub-pixels Px are rhombic, a length of its longest diagonal line is its maximum outer contour diameter size, if the length of its longest diagonal line is 1 μm, the length of the auxiliary electrodes 4 parallel to the direction where the long edge or the short edge is located is greater than 0.1 μm. For example, it may be 0.2 μm to 0.3 μm.

Further, the display panel further includes an encapsulation layer (not shown in the figure), and the encapsulation layer covers the light-emitting functional layer 3 and the plurality of auxiliary electrodes 4. The encapsulation layer 7 includes a first inorganic layer, an organic layer and a second inorganic layer sequentially arranged in a direction away from the array substrate 1. The first inorganic layer and the second inorganic layer are both transparent inorganic film layers, and their materials may include one or more of the following materials: Al₂O₃, TiO₂, ZrO₂, MgO, HFO₂, Ta₂O₅, Si₃N₄, AlN, SiN, SiNO, SiO, SiO₂, SiC, SiCNₓ, ITO, and IZO. These inorganic materials have both good light transmittance and excellent water-oxygen blocking performance. The material of the organic layer is transparent organic conductive resin, specifically including transparent matrix resin, conductive molecules and/or conductive ions. Specifically, it may be transparent conductive resin formed by stirring and completely dissolving organic acid doped polyaniline, cross-linked monomers, toluene, etc; or, conductive molecules such as polyaniline may be added to the transparent conductive resin mentioned above; or, conductive ions such as nanoscale antimony doped SiO₂ may be added to the transparent conductive resin mentioned above, and nanoscale conductive ions such as nanoscale indium tin oxide or nanoscale silver may also be used.

The first inorganic layer and the second inorganic layer made of inorganic substance materials completely cover the light-emitting functional layer 3 and the plurality of auxiliary electrodes 4, which can prevent water vapor from invading from the side and affecting the electrical performance of the light-emitting functional layer 3. A patterned organic layer has high elasticity and is sandwiched between the first inorganic layer and the second inorganic layer, which can suppress the cracking of the inorganic film, release stress between inorganic substances, and further improve the flexibility of the entire encapsulation layer, thereby achieving reliable flexible encapsulation.

### Second Embodiment

As shown in FIG. 6 and FIG. 7, a display panel provided in a second embodiment of the present application has a similar structure to the display panel provided in the first embodiment, except that the display panel further includes a touch control layer 6, and a plurality of touch control electrodes of the touch control layer 6 are electrically connected with auxiliary electrodes to form a touch control signal detection circuit.

Specifically, the display panel further includes a planarization layer 5 and a touch control layer 6, the planarization layer 5 covers a light-emitting functional layer 3 and a plurality of auxiliary electrodes 4, the touch control layer 6 is located on one side of the planarization layer 5 facing away from the planarization layer 5, the touch control layer 6 includes a plurality of touch control electrodes 60, the planarization layer 5 and covering portions 42 are provided with via holes H, and the touch control electrodes 60 are electrically connected with the conductive portions 41 through the via holes H.

Therefore, on the one hand, the auxiliary electrodes 4 can reduce an integral resistance of the second electrode layers 32, and relieve the voltage drop problem. On the other hand, the auxiliary electrodes 4 can further provide power to the touch control electrodes 60, thereby simplifying the circuit.

Further, orthographic projections of the touch control electrodes 60 on the array substrate 1 cover an orthographic projection of at least one pixel unit 30 on the array substrate 1. The touch control electrodes 60 may be formed by using transparent conductive materials, such as aluminum zinc oxide (AZO), gallium zinc oxide (GZO), and indium tin oxide (ITO). Each touch control electrode 60 may be powered by the auxiliary electrode 4 arranged by the at least one sub-pixel Px in the at least one pixel unit 30, specifically depending on a ratio of an area between the touch control electrode 60 and the sub-pixel Px.

In addition, the plurality of touch control electrodes 60 of the touch control layer 6 may be capacitive touch control electrodes, including self-capacitance and mutual-capacitance. The working principle of the touch control layer 6 is that when a finger approaches or touches a plane where the plurality of touch control electrodes 60 are located, the finger acts as a conductor, and a capacitance of the finger will be superimposed on a capacitance of the touch control layer 6, increasing the electric capacity of the touch control layer 6. During touch detection, the touch control layer 6 sequentially detects the plurality of touch control electrodes 60 respectively. Based on the changes in capacitance before and after touch, a coordinate X in a horizontal direction and a coordinate Y in a vertical direction are respectively determined, and then combined to form a planar touch coordinate. This is equivalent to projecting touch points on the touch control layer 6 separately to an X-axis direction and a Y-axis direction, then calculating the coordinates in the X-axis direction and the Y-axis direction, and finally combining them to form the coordinate of the touch points.

The plurality of touch control electrodes 60 of a touch control panel 1 may be capacitive touch control electrodes, including self-capacitance and mutual-capacitance. Taking a mutual-capacitive touch control layer 6 shown in FIG. 6 as an example, the plurality of touch control electrodes 60 include a touch control driving electrode 6a extending in the horizontal direction and a touch control sensing electrode 6b extending in the vertical direction. The position where the touch control driving electrode 6a and the touch control sensing electrode 6b intersect forms a capacitance. When an excitation signal is applied to the touch control driving electrode 6a, due to the presence of the mutual-capacitance, the excitation signal may be sensed and received on the touch control sensing electrode 6b. The magnitude and phase shift of the received signal are related to the frequency of the excitation signal and the size of the mutual-capacitance. In other words, the touch position is determined according to the capacitance between the touch control driving electrode 6a and the touch control sensing electrode 6b.

Further, the display panel further includes an encapsulation layer 7, and the encapsulation layer 7 is located on one side of the touch control layer 6 facing away from the array substrate 1.

As shown in FIG. 8, an embodiment of the present application further provides a preparation method for the display panel as described earlier, including the following steps S1 to S4.

Step S1, an array substrate 1 is provided, wherein a plurality of first electrodes 11 arranged in an array are formed on the array substrate 1;
step S2, a pixel limiting layer 2 is formed on the array substrate 1, wherein the pixel limiting layer 2 includes a plurality of pixel openings 21, and the pixel openings 21 expose at least part of the first electrodes 11;
step S3, a plurality of auxiliary electrodes 4 are formed on the pixel limiting layer 2, wherein the auxiliary electrodes 4 include conductive portions 41 and covering portions 42 located on one sides of the conductive portions 41 facing away from the array substrate 1, and orthographic projections of the covering portions 42 on the array substrate-1 cover orthographic projections of the conductive portions 41 on the array substrate 1; and
step S4, a light-emitting functional layer 3 is evaporated on the pixel limiting layer 2 and the plurality of auxiliary electrodes 4, wherein the light-emitting functional layer 3 includes a plurality of pixel units 30, the pixel units 30 include a plurality of sub-pixels Px, the sub-pixels Px include light-emitting structures 31 located on the first electrodes 11 and second electrode layers 32 located on the light-emitting structures 31, and the second electrode layers 32 are disconnected at edges of the auxiliary electrodes 4; and peripheral edges of the sub-pixels Px are not parallel to a direction where a long edge or a short edge of the display panel is located, the auxiliary electrodes 4 are arranged close to the peripheral edge of the at least one sub-pixel Px and extend parallel to a direction where the long edge and the short edge are located, so that the second electrode layers are capable of overlapping with the conductive portions 41 to achieve electrical connection.

In this embodiment, the first electrodes 11 are first etched on one side of the array substrate 1, then the pixel limiting layer 2 is formed by deposition, the plurality of auxiliary electrodes 4 are then formed on the pixel limiting layer 2, and the light-emitting functional layer 3 is evaporated. During evaporation, an evaporation source is located above the array substrate 1 and a fine metal mask. The light-emitting structure 31 is first evaporated, and then the second electrode layers 32 are evaporated. The second electrode layers 32 are disconnected at the covering portions 42 of the auxiliary electrodes 4, and are overlapped and connected with the conductive portions 41 according to an adjusted evaporation angle θ.

Further, in step S3, forming the plurality of auxiliary electrodes 4 on the pixel limiting layer 2 includes:
step S31, a conductive layer is formed on the pixel limiting layer 2;
step S32: eave layers are formed on the conductive portions 41; and
step S33, the cave layers and the conductive layer are synchronously etched to form the covering portions 42 and the conductive portions 41 of the plurality of auxiliary electrodes 4 respectively. The specific etching process may refer to the prior art and will not be repeated.

Further, for the display panel described in the first embodiment, the preparation method further includes:
step S5: an encapsulation layer 7 is formed on the light-emitting functional layer 3 and the plurality of auxiliary electrodes 4.

Further, for the display panel described in the second embodiment, the preparation method further includes:
step S6, a patterned planarization layer 5 is formed on the light-emitting functional layer 3 and the plurality of auxiliary electrodes 4, wherein the planarization layer 5 and the covering portions 42 are provided with via holes; and
step S7, a touch control layer 6 is formed on one side of the planarization layer 5 facing away from the array substrate 1, wherein the touch control layer 6 includes a plurality of touch control electrodes, and the touch control electrodes are electrically connected with the conductive portions 41 through the via holes.

Further, the preparation method further includes:
step S8: an encapsulation layer 7 is formed on one side of the touch control layer 6 facing away from the array substrate.

According to the preparation method of the display panel provided by the embodiment of the present application, the plurality of auxiliary electrodes 4 are first formed on the pixel limiting layer 2, then the light-emitting functional layer 3 is evaporated in a pixel opening 21 area, and the auxiliary electrodes 4 are arranged close to the peripheral edge of the at least one sub-pixel Px, so that the auxiliary electrodes 4 extend parallel to the direction where the long edge and the short edge are located. As a result, the second electrode layers 32 (i.e., the cathode layer) with the irregular sub-pixels Px can be made suitable for existing commonly used evaporation equipment for evaporating rectangular sub-pixels, allowing for forming of effective overlap between the second electrode layers 32 and the auxiliary electrodes 4, thereby improving uniformity of display brightness without the need for additional development of the evaporation equipment, which has high feasibility and greatly reduces a manufacturing cost while meeting a better display effect.

It should be easily understood that terms “on”, “above” and “over” in the present application should be interpreted in the widest possible way, so that “on” not only means “directly on something”, but also includes “on something” with intermediate features or layers between them, and “above” or “over” not only includes the meaning of “above something” or “over something”, and may further include the meaning of “above something” or “over something” without any intermediate features or layers between them (i.e. directly on something).

The term “base substrate” used in the text refers to a material on which subsequent material layers are added. The base substrate itself can be patterned. The material added to a top of the base substrate may be patterned or kept non-patterned. In addition, the base substrate may include a series of materials within a wide range, such as silicon, germanium, gallium arsenide, and indium phosphide. Alternatively, the base substrate may be made of non-conductive materials such as glass, plastic, or a sapphire wafer.

A term “layer” used in the text may refer to a material portion that includes a region with a certain thickness. The layer may extend over an entire lower-layer structure or an overlying structure, or have a smaller range than the lower-layer structure or the overlying structure. In addition, the layer may be a region of homogeneous or non-homogeneous continuous structure, with a thickness smaller than that of the continuous structure. For example, the layer may be located between a top surface and a bottom surface of the continuous structure, or between any paired transverse planes at the top surface and the bottom surface. The layer may extend horizontally, vertically, and/or along a conical surface. The base substrate may be a layer, which may include one or more layers, and/or may have one or more layers located on, above, and/or below it. The layer may include the plurality of layers. For example, an interconnect layer may include one or more conductor and contact layers (forming contacts, interconnection lines, and/or via holes within them), and one or more dielectric layers.

Finally, it should be noted that all the above embodiments are only used to illustrate the technical solutions of the present application but not used to limit it. Although the present application has been illustrated in detail with reference to the aforementioned embodiments, those skilled in the art should understand that they can still modify the technical solutions recorded in all the aforementioned embodiments, or equivalently replace part or all of the technical features thereinto. However, these modifications or replacements do not make the nature of the corresponding schemes separate from the scope of the technical solutions of all the embodiments of the present application.

What is claimed is:

1. A display panel, having a long edge and a short edge which are perpendicular to each other, wherein the display panel comprises an array substrate, as well as a pixel limiting layer and a light-emitting functional layer formed sequentially on the array substrate, a plurality of first electrodes arranged in an array are formed on the array substrate, the pixel limiting layer comprises a plurality of pixel openings, and the pixel openings expose at least part of the first electrodes; and the light-emitting functional layer comprises a plurality of pixel units, the pixel units comprise a plurality of sub-pixels, and the sub-pixels comprise light-emitting structures located on the first electrodes and second electrode layers located on the light-emitting structures; wherein
the display panel further comprises a plurality of auxiliary electrodes located on one side of the pixel limiting layer facing away from the array substrate, the second electrode layers are disconnected at edges of the auxiliary electrodes, the auxiliary electrodes comprise conductive portions and covering portions located on one sides of the conductive portions facing away from the array substrate, and orthographic projections of the covering portions on the array substrate cover orthographic projections of the conductive portions on the array substrate; and
peripheral edges of the sub-pixels of the pixel units are not parallel to a direction where the long edge or the short edge of the display panel is located, the auxiliary electrodes are arranged close to the peripheral edge of the at least one sub-pixel, and the auxiliary electrodes extend parallel to the direction where the long edge and the short edge are located, so that ends of the second electrode layers are capable of overlapping with the conductive portions to achieve electrical connection.

2. The display panel of claim 1, wherein the auxiliary electrodes comprise first transfer portions and second transfer portions which are arranged perpendicular to and intersecting with each other, and the auxiliary electrodes are arranged close to at least one edge of the peripheral edges of the sub-pixels.

3. The display panel of claim 1, wherein the auxiliary electrodes comprise first transfer portions and second transfer portions which are arranged perpendicular to each other and at intervals, the peripheral edges of the sub-pixels comprise a plurality of edges, and the first transfer portions and the second transfer portions are arranged respectively close to different edges.

4. The display panel of claim 1, wherein a ratio between lengths of the auxiliary electrodes parallel to the direction where the long edge or the short edge is located and lengths of maximum outer contour diameters of the sub-pixels is greater than 1:10.

5. The display panel of claim 1, wherein shapes of the sub-pixels are any one or a combination of at least two of a circle, an ellipse, or a polygon.

6. The display panel of claim 1, further comprising an encapsulation layer, wherein the encapsulation layer covers the light-emitting functional layer and the plurality of auxiliary electrodes.

7. The display panel of claim 1, further comprising a planarization layer and a touch control layer, wherein the planarization layer covers the light-emitting functional layer and the plurality of auxiliary electrodes, the touch control layer is located on one side of the planarization layer facing away from the array substrate, the touch control layer comprises a plurality of touch control electrodes, the planarization layer and the covering portions are provided with via holes, and the touch control electrodes are electrically connected with the conductive portions through the via holes.

8. The display panel of claim 7, wherein orthographic projections of the touch control electrodes on the array substrate covers an orthographic projection of the at least one pixel unit on the array substrate.

9. The display panel of claim 7, further comprising an encapsulation layer, wherein the encapsulation layer is located on one side of the touch control layer facing away from the array substrate.

10. The display panel according to claim 6, wherein the encapsulation layer comprises a first inorganic layer, an organic layer and a second inorganic layer sequentially arranged in a direction away from the array substrate.

11. A preparation method of a display panel, comprising:
providing an array substrate, wherein a plurality of first electrodes arranged in an array are formed on the array substrate;
forming a pixel limiting layer on the array substrate, wherein the pixel limiting layer comprises a plurality of pixel openings, and the pixel openings expose at least part of the first electrodes;
forming a plurality of auxiliary electrodes on the pixel limiting layer, wherein the auxiliary electrodes comprise conductive portions and covering portions located on one sides of the conductive portions facing away from the array substrate, and orthographic projections of the covering portions on the array substrate cover orthographic projections of the conductive portions on the array substrate; and
evaporating a light-emitting functional layer on the pixel limiting layer and the plurality of auxiliary electrodes, wherein the light-emitting functional layer comprises a plurality of pixel units, the pixel units comprise a plurality of sub-pixels, the sub-pixels comprise light-emitting structures located on the first electrodes and second electrode layers located on the light-emitting structures, and the second electrode layers are disconnected at edges of the auxiliary electrodes; and peripheral edges of the sub-pixels are not parallel to a direction where a long edge or a short edge of the display panel is located, the auxiliary electrodes are arranged close to the peripheral edge of the at least one sub-pixel, and the auxiliary electrodes extend parallel to a direction where the long edge and the short edge are located, so that the second electrode layers are capable of overlapping with the conductive portions to achieve electrical connection.

12. The preparation method according to claim 11, wherein forming the plurality of auxiliary electrodes on the pixel limiting layer comprises:
forming a conductive layer on the pixel limiting layer;
forming eave layers on the conductive portions; and
synchronously etching the eave layers and the conductive layer to form the covering portions and conductive portions of the plurality of auxiliary electrodes respectively.

13. The preparation method according to claim 11, further comprising:
forming an encapsulation layer on the light-emitting functional layer and the plurality of auxiliary electrodes.

14. The preparation method according to claim 11, further comprising:
forming a patterned planarization layer on the light-emitting functional layer and the plurality of auxiliary electrodes, wherein the planarization layer and the covering portions are provided with via holes; and
forming a touch control layer on one side of the planarization layer facing away from the array substrate, wherein the touch control layer comprises a plurality of touch control electrodes, and the touch control electrodes are electrically connected with the conductive portions through the via holes.

15. The preparation method according to claim 14, further comprising:
forming an encapsulation layer on one side of the touch control layer facing away from the array substrate.
